(19) United States
(12) Patent Application Publication
(10) Pub. No.: US 2024/0413070 A1
(43) Pub. Date: Dec. 12, 2024

(54) VIAS INCLUDING A POROUS ELECTRICALLY CONDUCTIVE MATERIAL AND METHODS FOR FABRICATING THE VIAS

(71) Applicant: CORNING INCORPORATED, CORNING, NY (US)

(72) Inventors: Sean Matthew Garner, Elmira, NY (US); Dhananjay Joshi, Painted Post, NY (US); Chukwudi Azubuike Okoro, Painted Post, NY (US)

(21) Appl. No.: 18/700,432

(22) PCT Filed: Sep. 28, 2022
(86) PCT No.: PCT/US2022/044973

§ 371 Date: Apr. 11, 2024

Related U.S. Application Data
(60) Provisional application No. 63/270,162, filed on Oct. 21, 2021.

(51) Int. Cl. H01L 23/498; B22F 3/15; H01L 21/48; H01L 23/15; H01L 23/48

(52) U.S. Cl. CPC H01L 23/49827; B22F 3/15; H01L 21/486; H01L 23/15; H01L 23/481

(57) ABSTRACT

A via includes a substrate and a porous electrically conductive material. The substrate includes a first surface and a second surface opposite to the first surface. The substrate includes a through-hole extending from the first surface to the second surface. The porous electrically conductive material extends through the through-hole. The porous electrically conductive material includes a first porosity in a central region of the through-hole and a second porosity less than the first porosity proximate the first surface and the second surface of the substrate.

### CROSS-REFERENCE TO RELATED APPLICATIONS

This application claims the benefit of priority under 35 U.S.C. § 119 of U.S. Provisional Application Ser. No. 63/270,162, filed on Oct. 21, 2021, the content of which is incorporated herein by reference in its entirety.

### BACKGROUND

### Field

The present disclosure relates generally to vias. More particularly, it relates to vias including a porous electrically conductive material.

### Technical Background

The desire for miniaturization and improved electrical performance has resulted in the emergence of 3D and 2.5D chip stacking architectures, which use vertical electrical interconnects. These vertical interconnects may be fabricated by forming holes through substrates and forming a conductive path within each hole, resulting in short interconnects having a high electrical performance. Through-silicon via (TSV) has been the most prominent vertical interconnect. The challenges associated with 3D stacking of chips, however, has shifted attention to 2.5D chip stacking architectures, as 2.5D chip stacking architectures are less expensive and present fewer integration challenges. The 2.5D chip stacking architectures may be realized by the use of non-active substrates (having no integrated front end devices) with vertical interconnects, which are often referred to as interposers. Interposer substrates may be made of silicon or glass.

Glass interposers with through-glass vias (TGV) are attractive due to the many advantages of glass over silicon that includes lower cost, tunable coefficient of thermal expansion (CTE), and superior high frequency performance. The formation of TGVs, however, presents thermo-mechanical challenges that arise due to the CTE mismatch between the glass matrix (e.g., about 0.6 ppm/° C. for fused silica) and the metal fill (e.g., copper is about 16.7 ppm/° C.). This CTE difference leads to high stress buildup during thermal cycling that results in different failure modes, such as cracks in the substrate, via voiding, sidewall delamination, etc.

### SUMMARY

Some embodiments of the present disclosure relate to a via. The via includes a substrate and a porous electrically conductive material. The substrate includes a first surface and a second surface opposite to the first surface. The substrate includes a through-hole extending from the first surface to the second surface. The porous electrically conductive material extends through the through-hole. The porous electrically conductive material includes a first porosity in a central region of the through-hole and a second porosity less than the first porosity proximate the first surface and the second surface of the substrate.

Yet other embodiments of the present disclosure relate to a via. The via includes a substrate, a porous electrically conductive material, and a cavity. The substrate includes a first surface and a second surface opposite to the first surface. The substrate includes a through-hole extending from the first surface to the second surface. The porous electrically conductive material extends completely through the through-hole. The cavity is in the porous electrically conductive material in a central region of the through-hole.

Yet other embodiments of the present disclosure relate to a method for fabricating a via. The method includes forming a through-hole through a substrate from a first surface of the substrate to a second surface of the substrate opposite to the first surface. The method includes filling the through-hole with a paste comprising an electrically conductive material. The method includes sintering the paste to form a porous metallized through-hole comprising a first porosity. The method includes applying hot-isostatic pressure to the porous metallized through-hole to change the porosity of the porous metallized through-hole proximate the first surface and the second surface of the substrate to a second porosity less than the first porosity.

The methods for fabricating the vias disclosed herein result in the formation of vias including at least three horizontal layers of paste metallization in a through-glass via (TGV), where the central horizontal layer of paste metallization is more porous than the outer horizontal layers of paste metallization at the ends of the TGV. This may be achieved by conditioning of an originally one layer paste metallization rather than by the application of nano-sized paste metallization at the ends of the TGV. The conditioning may be achieved by the application of hot-isostatic pressure (HIP), where uniform temperature, pressure, and time is applied on all surfaces of the structure. The vias disclosed herein exhibit a low surface roughness (e.g., less than or equal to about 300 nanometers root mean square) on both ends of the TGV, thereby enabling improved electrical performance due to minimized contact resistance and increased redistribution layer (RDL) metallization continuity. The vias disclosed herein enable the use of highly electrically conductive materials, such as copper and silver, which have high coefficient of thermal expansion (CTE) values without sacrificing the reliability of the vias by controlling the porosity and surface roughness of the vias. The cost of the TGV metallization disclosed herein may also be reduced compared to typical paste-based metallization since surface roughness is controlled through conditioning rather than by using expensive nano-particle based caps at the ends of the TGV. The vias may have any suitable shape, such as a cylindrical shape, a tapered shape, or an hour-glass shape. In addition, the use of HIP enables improved liquid hermeticity through increased densification leading to improved interface bonding between substrates and paste metallization and between the paste particles.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary and are intended to provide an overview or framework to understanding the nature and character of the claims. The accompanying drawings are included to provide a further understanding and are incorporated in and constitute a part of this specification. The drawings illustrate one or more embodiment(s), and together with the description explain principles and operation of the various embodiments.

### BRIEF DESCRIPTION OF THE DRAWINGS

FIG. 1 is a cross-sectional view of an exemplary via;

FIG. 2 is a cross-sectional view of another exemplary via;

FIGS. 3A-3C are cross-sectional views of exemplary through-holes;

FIG. 4 is a cross-sectional view of an exemplary metallized through-hole;

FIG. 5 is a cross-sectional view of an exemplary metallized through-hole after applying hot-isostatic pressure to the metallized through-hole of FIG. 4;

FIG. 6 is a cross-sectional view of another exemplary metallized through-hole after applying hot-isostatic pressure to the metallized through-hole of FIG. 4; and

FIGS. 7A and 7B are flow diagrams illustrating an exemplary method for fabricating a via.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. However, this disclosure may be embodied in many different forms and should not be construed as limited to the embodiments set forth herein.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom, vertical, horizontal—are made only with reference to the figures as drawn and are not intended to imply absolute orientation.

Unless otherwise expressly stated, it is in no way intended that any method set forth herein be construed as requiring that its steps be performed in a specific order, nor that with any apparatus, specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an,” and “the” include plural references unless the context clearly dictates otherwise. Thus, for example, reference to “a” component includes aspects having two or more such components, unless the context clearly indicates otherwise.

Micro light-emitting diode (microLED) display applications have received interest due to their higher brightness, higher illuminance, and longer lifetime compared to other display applications. For tiled microLED displays, an electrical interconnect may connect a microLED on one surface of a backplane to integrated circuit (IC) drivers on a backside of the backplane. While there are different technologies for achieving these interconnects, the use of metallized through-glass vias (TGVs) as the electrical interconnect for glass based backplanes may offer improved electrical performance compared to other alternatives. Therefore, the use of metallized TGVs in microLED displays may be desirable. Use of metallized TGVs may also be desired for other display and non-display applications, such as liquid crystal displays, organic light-emitting diode (OLED) displays, photovoltaic devices, interposers, micro electro-mechanical systems (MEMS), and other devices and applications where interconnection between the substrate top and bottom surfaces is desired.

The high temperature processing requirements of thin-film transistor (TFT) active matrix backplanes utilized in microLED and other display technologies, however, leads to a large thermal expansion mismatch between the metallized TGV and the glass substrate, resulting in the buildup of stresses which may lead to the formation of cracks that may result in product failure. There is a correlation between metallization thickness and the formation of cracks in the glass substrate. For example, a conformal sidewall copper thickness of less than about 12 micrometers may prevent crack formation for a fused silica glass substrate that is subjected to a maximum temperature of 400 degrees Celsius. For microLED backplane and other thin film device applications, however, the resulting non-planar surface of the conformal metallization is not appropriate and leads to device discontinuities, high contact resistance, and fabrication yield loss. In addition, fully-filled electroplated TGVs may result in cracks in the substrate due to the CTE mismatch, thus fully-filled electroplated TGVs are also not appropriate for microLED backplane applications. Other solutions have included a less than about 12 micrometer thick copper conformal plating on the via wall with the remaining portion of the via, typically having a diameter greater than about 50 micrometers, filled with another material. These solutions, however, introduce an additional material that compounds the TFT or thin film device process compatibility issues.

While the use of typical paste-based metallization may be used to achieve a fully filled TGV, typical paste-based metallization also has the aforementioned drawbacks as well as high surface roughness which results in high contact resistance and/or open circuits when the TGV is connected to a redistribution layer. To achieve good surface roughness, typically, finer sized particles are deposited at the ends of the TGV. Alternatively, a different material such as electroplated copper may be deposited at the ends of the TGV. The addition of these finer sized particles leads to increased cost due to the higher cost of the nano-sized particles, as well as a longer production time, as a minimum of two additional processing steps are needed, one for each side of the substrate.

To mitigate against the aforementioned drawbacks, disclosed herein is a paste-based TGV, having at least two horizontal layers, having two or more porosities. The least porous layers are at the end(s) of the TGV, while the more porous layer is at the central region of the TGV and accounts for more than about 50 percent of the metallized TGV. The least porous layers of the metallized TGV may be achieved by the application of hot-isostatic pressure (HIP), rather than by the application of a different layer, material, and/or material size. As disclosed herein, a conductive paste filled TGV with varying porosity in the depth of the TGV is achieved with a single particle size distribution paste and is compatible with TFT and other elevated temperature thin film device processing. Porosity is a measure of the void spaces in a material, and is a fraction of the volume of voids over the total volume as a percentage between 0 percent and 100 percent. Porosity may be measured using, for example, X-ray computed tomography, scanning electron microscopy (SEM), optical microscopy, transmission electron microscopy (TEM), etc. The microscopy methods may be combined with image processing techniques to measure porosity.

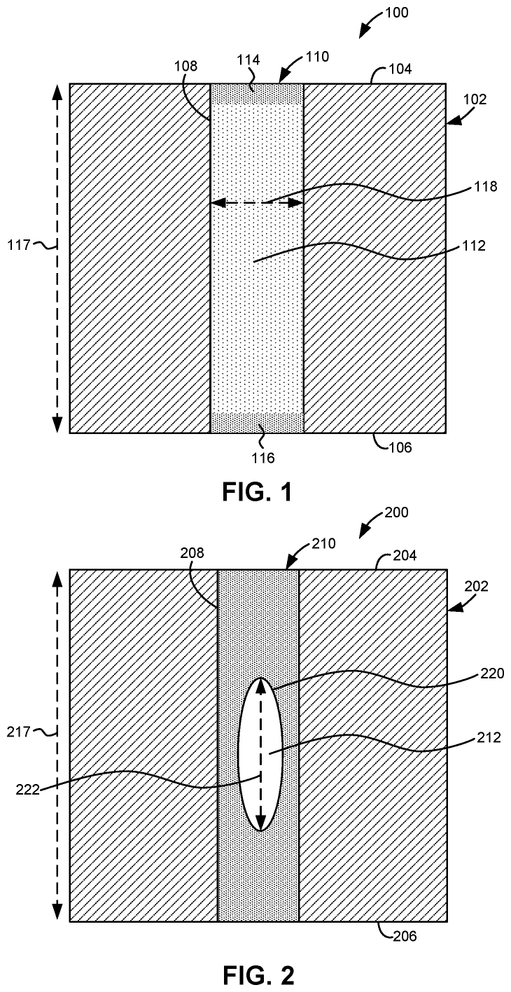

Referring now to FIG. 1, a cross-sectional view of an exemplary via 100 is depicted. Via 100 includes a substrate 102 and a porous electrically conductive material (e.g., metal) 110. The substrate 102 includes a first surface 104 and a second surface 106 opposite to the first surface 104. A through-hole 108 extends through the substrate 102 from the first surface 104 to the second surface 106. In alternative examples, a blind via exists that is only open at one surface instead of a through-hole and has a depth of greater than about 50 percent, greater than about 70 percent, or greater than about 90 percent of the substrate thickness. Further examples of through-holes can also be applied to blind via embodiments. In certain exemplary embodiments, the substrate 102 may be a silicon substrate. In other embodiments, the substrate 102 may be a non-silicon substrate, such as a glass substrate, a ceramic substrate, or a glass-ceramic substrate. In yet other embodiments, the substrate 102 may include Alumina, AlN, Quartz (Sapphire), InGaN, GaAs, InGaAs, GaP, GaSb, InP, InAs, InSb, GaN on Sapphire, SOI, SIMOX, Ge, crystal aluminum oxide (Garnet), or another suitable material or combination thereof. The substrate 102 may have a thickness 117 between the first surface 104 and the second surface 106 within a range, for example, from about 0.1 millimeters to about 2 millimeters.

The porous electrically conductive material 110 extends through the through-hole 108 from the first surface 104 to the second surface 106 of the substrate 102. The porous electrically conductive material 110 includes a first porosity in a central region 112 of the through-hole 108. The porous electrically conductive material 110 includes a second porosity less than the first porosity proximate the first surface 104 of the substrate 102 as indicated at 114 (e.g., at the end of the through-hole 108 adjacent to the first surface 104) and proximate the second surface 106 of the substrate 102 as indicated at 116 (e.g., at the end of the through-hole 108 adjacent to the second surface 106). In other words, the porous electrically conductive material 110 includes a first density in the central region 112 of the through-hole 108 and a second density greater than the first density proximate the first surface 104 as indicated at 114 and proximate the second surface 106 as indicated at 116. In the case of a blind via, the increased density of the porous electrically conductive material 110 is only at a single substrate surface. In certain exemplary embodiments, the first porosity is at least two times the second porosity. The porous electrically conductive material may include a gradient porosity between the first porosity at the central region 112 of the through-hole 108 and the second porosity at the end regions 114 and 116 of the through-hole 108. In some embodiments, the porous electrically conductive material including the first porosity in the central region 112 of the through-hole 108 may extend at least about 50 percent of the via length 117.

In certain exemplary embodiments, the porous electrically conductive material 110 includes a sintered electrically conductive paste including electrically conductive particles including a substantially uniform size (e.g., within plus or minus 10 percent). The particle size of the porous electrically conductive material 110 is based on the particle size of the electrically conductive paste prior to sintering. In other embodiments, the size of the electrically conductive particles within the sintered electrically conductive paste may have a variable distribution with the particles varying in size between about 2 micrometers and about 5 micrometers. A surface roughness of the porous electrically conductive material 110 proximate the first surface 104 (e.g., aligned with the first surface 104) and proximate the second surface 106 (e.g., aligned with the second surface 106) of the substrate 102 may be less than about 300 nanometers root mean square. The first surface 104 of the substrate 102 and the exposed surface of porous electrically conductive material 110 aligned with the first surface 104 are compatible with the fabrication of a redistribution layer and/or thin-film devices (e.g., thin-film transistors) directly on the surfaces. Likewise, the second surface 106 of the substrate 102 and the exposed surface of porous electrically conductive material 110 aligned with the second surface 106 are also compatible with the fabrication of a redistribution layer and/or thin-film devices directly on the surfaces.

In one embodiment, the porous electrically conductive material 110 may include copper. In this case, the first porosity for a crack-free substrate 102 may be greater than or equal to about: 0.6263(d)-7.7368, where “d” is an average diameter 118 of the through-hole 108 greater than about 12 micrometers and less than about 100 micrometers. In another embodiment, the porous electrically conductive material 110 may include silver. In this case, the first porosity for a crack-free substrate 102 may be greater than or equal to about: 0.6 (0.6263(d)-7.7368), where “d” is an average diameter 118 of the through-hole 108 greater than about 12 micrometers and less than about 100 micrometers. These equations for a crack-free substrate 102 are based on a maximum stress threshold of about 140 megapascals to prevent crack formation, above which cracks may be formed in substrate 102. The porosity of the porous electrically conductive material 110 is based on the porosity of the electrically conductive paste prior to sintering and the parameters of the process (e.g., hot-isostatic pressure) used to form the porous electrically conductive material 110 after the electrically conductive paste is applied to substrate 102. In general, an increase in the porosity of the porous electrically conductive material 110 corresponds to a decrease in the induced stresses in the substrate 102, and thus a decrease in the likelihood of crack formation within the substrate 102.

FIG. 2 is a cross-sectional view of another exemplary via 200. Via 200 includes a substrate 202, a porous electrically conductive material 210, and a cavity 220. The substrate 202 includes a first surface 204 and a second surface 206 opposite to the first surface 204. A through-hole 208 extends through the substrate 202 from the first surface 204 to the second surface 206. Alternative examples with blind via structures are also possible. The porous electrically conductive material 210 extends completely through the through-hole 208 such that the via 200 remains electrically conductive notwithstanding the cavity 220. In certain exemplary embodiments, the porous electrically conductive material 210 may include copper, silver, or another suitable electrically conductive material. The cavity 220 is in the porous electrically conductive material 210 in a central region 212 of the through-hole 208. In some embodiments, the cavity 220 may include a length 222 greater than about 10 percent of a distance 217 between the first surface 204 and the second surface 206 of the substrate 202.

In certain exemplary embodiments, the porous electrically conductive material 210 includes a sintered electrically conductive paste including electrically conductive particles including a substantially uniform size (e.g., within plus or minus 10 percent). The substrate 202 may be similar to the substrate 102 previously described and illustrated with reference to FIG. 1 (e.g., substrate 202 may include a glass, a glass-ceramic, or a ceramic). A surface roughness of the porous electrically conductive material 210 proximate the first surface 204 (e.g., aligned with the first surface 204) and proximate the second surface 206 (e.g., aligned with the second surface 206) of the substrate 202 may be less than about 300 nanometers root mean square. The first surface 204 of the substrate 202 and the exposed surface of porous electrically conductive material 210 aligned with the first surface 204 are compatible with the fabrication of a redistribution layer and/or thin-film devices directly on the surfaces. Likewise, the second surface 206 of the substrate 202 and the exposed surface of porous electrically conductive material 210 aligned with the second surface 206 are also compatible with the fabrication of a redistribution layer and/or thin-film devices directly on the surfaces.

The porosity of the porous electrically conductive material 210 and the size of cavity 220 is based on the porosity of the electrically conductive paste prior to sintering and the parameters of the process (e.g., hot-isostatic pressure) used to form the porous electrically conductive material 210 after the electrically conductive paste is applied to substrate 202. In certain exemplary embodiments as illustrated in FIG. 2, the porosity of the porous electrically conductive material 210 may be substantially uniform throughout the through-hole 208. In other embodiments, the porous electrically conductive material 210 may include a first porosity proximate the central region 212 of the through-hole 208 and a second porosity less than the first porosity proximate the first surface 204 and the second surface 206 of the substrate 202.

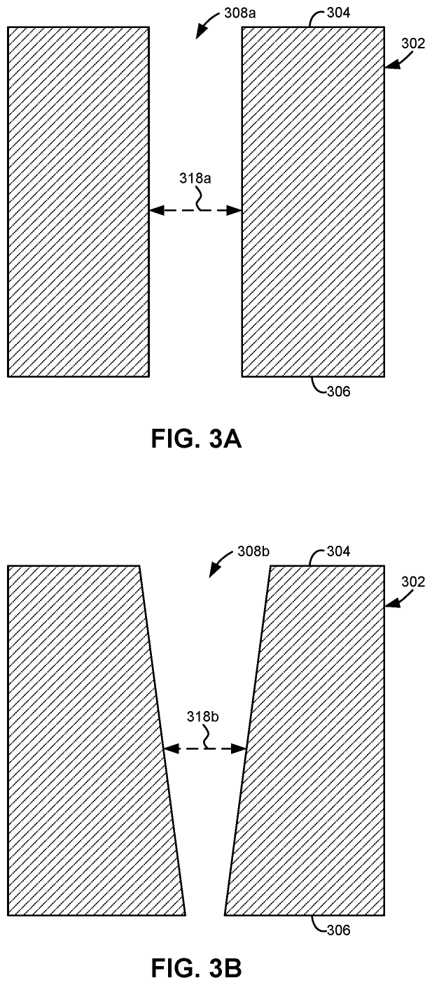

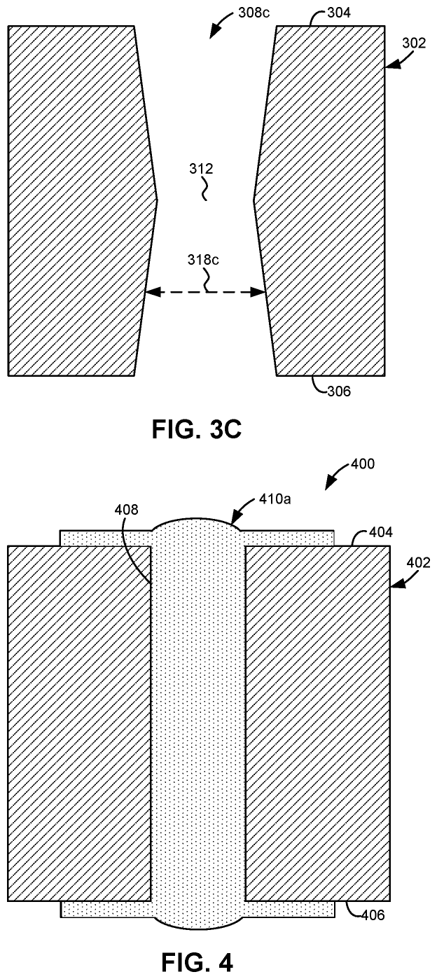

FIG. 3A is a cross-sectional view of an exemplary through-hole 308a. Through-hole 308a extends through a substrate 302 from a first surface 304 to a second surface 306 of the substrate 302. In this embodiment, through-hole 308a is cylindrical in shape. The diameter of the through-hole 308a proximate the first surface 304 may be about equal to the diameter of the through-hole 308a proximate the second surface 306. In certain exemplary embodiments, the through-hole 308a may have an average diameter 318a, for example, between about 12 micrometers and about 100 micrometers. The substrate 302 may be similar to the substrate 102 previously described and illustrated with reference to FIG. 1 (e.g., substrate 302 may be a glass substrate, a glass-ceramic substrate, or a ceramic substrate).

FIG. 3B is a cross-sectional view of an exemplary through-hole 308b. Through-hole 308b extends through substrate 302 from the first surface 304 to the second surface 306 of the substrate 302. In this embodiment, through-hole 308b is tapered in shape. The diameter of the through-hole 308b proximate the first surface 304 may be greater than the diameter of the through-hole 308b proximate the second surface 306. The diameter of the through-hole 308b may gradually decrease from the first surface 304 to the second surface 306. The through-hole 308b taper may be linear or non-linear in shape. Also, a blind via results when the diameter at the second surface 306 is zero (closed). In examples, thin film devices or other electrically functional elements can exist on the first surface, second surface, or both surfaces. In certain exemplary embodiments, the through-hole 308b may have an average diameter 318b, for example, between about 12 micrometers and about 100 micrometers.

FIG. 3C is a cross-sectional view of an exemplary through-hole 308c. Through-hole 308c extends through substrate 302 from the first surface 304 to the second surface 306 of the substrate 302. In this embodiment, through-hole 308c is hour-glass shaped. The diameter of the through-hole 308c proximate the first surface 304 may be about equal to the diameter of the through-hole 308c proximate the second surface 306. Alternatively, the difference in diameters at the two surfaces may be less than about 10 times, less than about 5 times, or less than about 2 times of each other. The diameter of the through-hole 308c in a central region 312 may be less than the diameter of the through-hole 308c proximate the first surface 304 and less than the diameter of the through-hole 308c proximate the second surface 306. The diameter of the through-hole 308c may gradually decrease from the first surface 304 to the central region 312 and from the second surface 306 to the central region 312. The through-hole 308c taper may be linear or non-linear in shape, and the location of minimum diameter may occur in the center or be offset. In certain exemplary embodiments, the through-hole 308c may have an average diameter 318c, for example, between about 12 micrometers and about 100 micrometers.

The through-holes 308a, 308b, and 308c of FIGS. 3A-3C may be formed by any suitable process. For example, through-holes 308a, 308b, and 308c may be formed by photolithography and etching processes, laser damage and etching processes, and/or drilling processes (e.g., laser drilling). Depending on the substrate material, utilized etching processes may be wet etchant, vapor etchant, plasma etchant, or other.

FIG. 4 is a cross-sectional view of an exemplary metallized through-hole 400. Metallized through-hole 400 includes a substrate 402 including a first surface 404 and a second surface 406 opposite to the first surface 404. The substrate 402 includes a through-hole 408 extending from the first surface 404 to the second surface 406. While through-hole 408 is a cylindrical through-hole in this example, in other examples, through-hole 408 may be a tapered through-hole (e.g., 308b of FIG. 3B), an hour-glass through-hole (e.g., 308c of FIG. 3C), or another suitably shaped through-hole or blind via.

Through-hole 408 is filled with a paste including an electrically conductive material. The paste may also be applied on the first surface 404 and/or the second surface 406 proximate the through-hole 408. The paste may be a sinter paste including electrically conductive (e.g, metal) particles, binders (e.g., organic and/or inorganic), solvents, and/or fillers (e.g., glass frits, such as lead silicate). The electrically conductive particles may be substantially uniform in size (e.g., vary in size by no more than 10 percent) and may have an average diameter, for example, within a range between about 2 micrometers and about 5 micrometers. For the uniform conductive paste applied to the through-hole, different average particle sizes and particle size distributions are also possible. The electrically conductive particles may include copper particles, silver particles, or other suitable electrically conductive particles. After applying the paste to the through-hole 408 of substrate 402, the paste may be sintered to form a porous electrically conductive material 410a. The paste may be sintered to a temperature, for example, greater than about 500 degrees Celsius to fuse the electrically conductive particles to each other to form the porous electrically conductive material 410a. The sintering temperature used is dependent on the specific paste and conductive particles. As examples, this temperature can be greater than about 200 degrees Celsius, greater than about 300 degrees Celsius, greater than about 400 degrees Celsius, or greater than about 500 degrees Celsius. Porous electrically conductive material 410a includes a first porosity throughout the porous electrically conductive material.

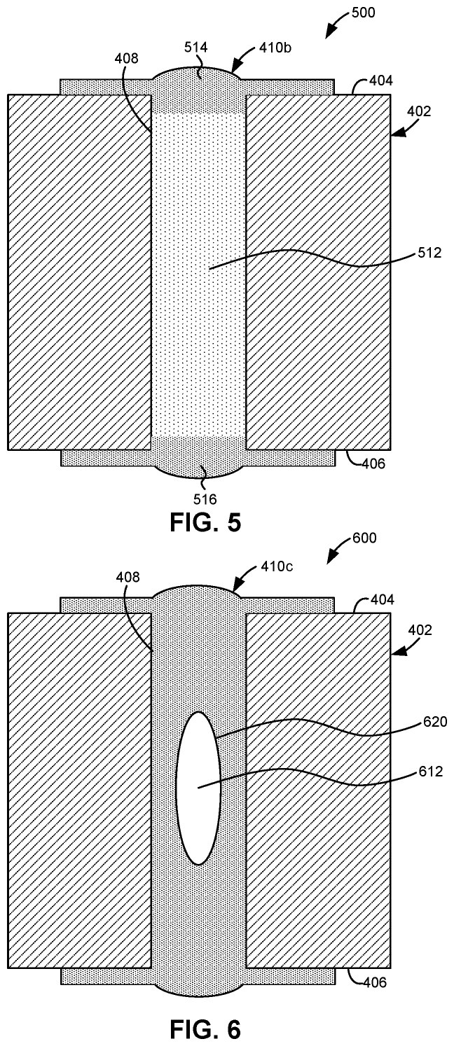

FIG. 5 is a cross-sectional view of an exemplary metallized through-hole 500 after applying hot-isostatic pressure to the metallized through-hole 400 of FIG. 4. Hot-isostatic pressure is applied to the metallized through-hole 400 to change the porosity (and the density) of the porous electrically conductive material 410a proximate the first surface 404 and the second surface 406 of the substrate 402 to a second porosity less than the first porosity to form porous electrically conductive material 410b. While hot-isostatic pressure is used as an example, other methods may also be used to modify the surface and center densities relative to each other. Porous electrically conductive material 410b includes the first porosity in a central region 512 of the through-hole 408 and the second porosity proximate the first surface 404 as indicated at 514 and proximate the second surface 406 as indicated at 516. The porous electrically conductive material 410b may include a gradient porosity between the first porosity at the central region 512 of the through-hole 408 and the second porosity at the end regions 514 and 516 of the through-hole 408. The regions of the porous electrically conductive material 410b near the first surface 404 and the second surface 406 may differ depending upon the specific through-hole or blind via geometry, paste filling process parameters, and sintering process parameters. For example, the porous electrically conductive material 410b may have different densities, gradients, and surface roughness on the first surface 404 and the second surface 406.

In certain exemplary embodiments, the hot-isostatic pressure may include a temperature greater than or equal to about 200 degrees Celsius (e.g., 600 degrees Celsius), a dwell time greater than or equal to about 30 minutes (e.g., 180 minutes), and a pressure greater than or equal to about 4 megapascals (e.g., 4 megapascals). In addition to changing the porosity, the hot-isostatic pressure also reduces the surface roughness of the porous electrically conductive material 410b. In certain exemplary embodiments, the hot-isostatic pressure may reduce the surface root mean square roughness by up to about 34 percent and reduce the peak-to-valley values by up to about 43 percent. As another example, the resulting surface root mean square roughness can be less than about 0.5 micrometers or less than about 0.3 micrometers, and the peak-to-valley roughness can be less than about 3 micrometers. The porous electrically conductive material 410b may be planarized (e.g., using chemical-mechanical polishing or another suitable process) to form the via 100 previously described and illustrated with reference to FIG. 1.

FIG. 6 is a cross-sectional view of another exemplary metallized through-hole 600 after applying hot-isostatic pressure to the metallized through-hole 400 of FIG. 4. Hot-isostatic pressure is applied to the metallized through-hole 400 to change the porosity (and the density) of the porous electrically conductive material 410a to form porous electrically conductive material 410c. Porous electrically conductive material 410c includes a second porosity less than the first porosity and a cavity 620 in a central region 612 of the through-hole 408. Porous electrically conductive material 410c may be formed by using higher values for the HIP parameters than used to form porous electrically conductive material 410b of FIG. 5.

In certain exemplary embodiments, the hot-isostatic pressure may include a temperature greater than or equal to about 500 degrees Celsius (e.g., 600 degrees Celsius), a dwell time greater than or equal to about 120 minutes (e.g., 120 minutes), and a pressure greater than or equal to about 20 megapascals (e.g., 20 megapascals). In addition to changing the porosity and forming a cavity, the hot-isostatic pressure also reduces the surface roughness of the porous electrically conductive material 410c. In certain exemplary embodiments, the hot-isostatic pressure may reduce the surface root mean square roughness by up to about 34 percent and reduce the peak-to-valley values by up to about 43 percent. The porous electrically conductive material 410c may be planarized (e.g., using chemical-mechanical polishing or another suitable process) to form the via 200 previously described and illustrated with reference to FIG. 2.

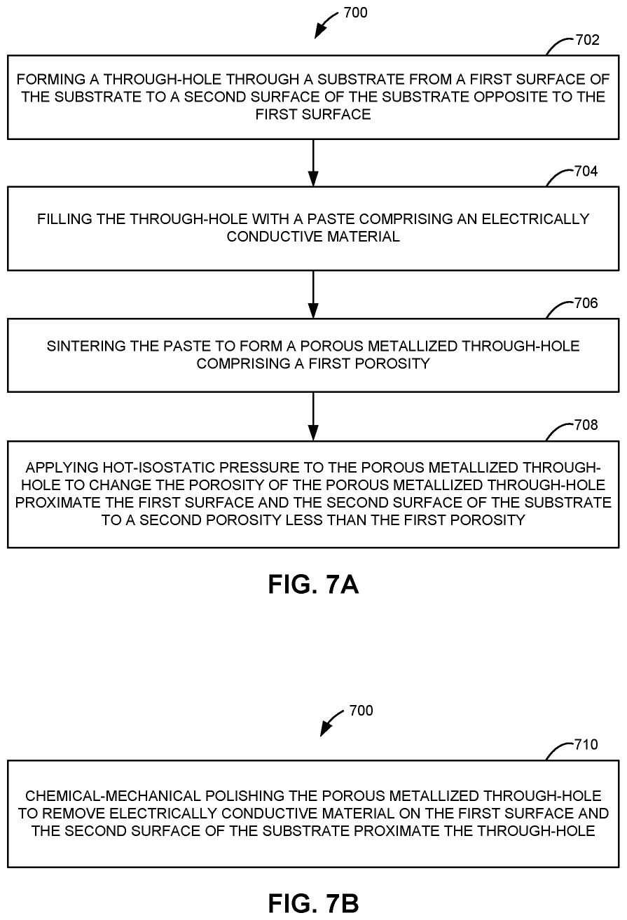

FIGS. 7A and 7B are flow diagrams illustrating an exemplary method 700 for fabricating a via, such as via 100 of FIG. 1 or via 200 of FIG. 2. As illustrated in FIG. 7A at 702, method 700 includes forming a through-hole (e.g., 108, 208, 308a, 308b, 308c, or 408) through a substrate (e.g., 102, 202, 302, or 402) from a first surface (e.g., 104, 204, 304, or 404) of the substrate to a second surface (e.g., 106, 206, 306, or 406) of the substrate opposite to the first surface. In certain exemplary embodiments, the substrate comprises a glass, a glass-ceramic, or a ceramic. Forming the through-hole may comprise forming a cylindrical through-hole (e.g., 308a), a tapered through-hole (e.g., 308b) including blind via, or an hour-glass through-hole (e.g., 308c). At 704, method 700 includes filling the through-hole with a paste (e.g., sinter paste) comprising an electrically conductive material (e.g., copper, silver, etc.). At 706, method 700 includes sintering the paste to form a porous metallized through-hole (e.g, 400) comprising a first porosity. At 708, method 700 includes applying hot-isostatic pressure to the porous metallized through-hole to change the porosity of the porous metallized through-hole proximate the first surface and the second surface of the substrate to a second porosity less than the first porosity (e.g., as illustrated in FIGS. 5 and 6).

In certain exemplary embodiments, applying hot-isostatic pressure to the porous metallized through-hole comprises applying hot-isostatic pressure to the porous metallized through-hole to form a cavity (e.g., 220 or 620) in the electrically conductive material (e.g., 210 or 410c) in a central region (e.g., 212 or 612) of the through-hole. In other embodiments, the hot-isostatic pressure comprises a temperature greater than or equal to about 300 degrees Celsius, a dwell time greater than or equal to about 30 minutes, and a pressure greater than or equal to about 4 megapascals.

As illustrated in FIG. 7B at 710, method 700 may further include chemical-mechanical polishing the porous metallized through-hole (e.g., 500 or 600) to remove electrically conductive material on the first surface and the second surface of the substrate proximate the through-hole (e.g., to form via 100 of FIG. 1 or 200 of FIG. 2). The electrically conductive material may also be removed or avoided by other processes such as during the paste filling process. After processing of the paste filled via, the first surface and/or the second surface is compatible with thin film electronic device fabrication at temperatures greater than about 200 degrees Celsius, greater than about 300 degrees Celsius, greater than about 400 degrees Celsius, or greater than about 500 degrees Celsius.

It will be apparent to those skilled in the art that various modifications and variations can be made to embodiments of the present disclosure without departing from the spirit and scope of the disclosure. Thus, itis intended that the present disclosure cover such modifications and variations provided they come within the scope of the appended claims and their equivalents.

What is claimed is:

1. A via comprising:
a substrate comprising a first surface and a second surface opposite to the first surface, the substrate comprising a through-hole extending from the first surface to the second surface; and
a porous electrically conductive material extending through the through-hole, the porous electrically conductive material comprising a first porosity in a central region of the through-hole and a second porosity less than the first porosity proximate the first surface and the second surface of the substrate.

2. The via of claim 1, wherein the porous electrically conductive material comprises a sintered electrically conductive paste comprising electrically conductive particles comprising a substantially uniform size.

3. The via of claim 1, wherein the substrate comprises a glass, a glass-ceramic, or a ceramic.

4. The via of claim 1, wherein the first porosity is at least two times the second porosity.

5. The via of claim 1, wherein the porous electrically conductive material comprises a gradient porosity between the first porosity and the second porosity.

6. The via of claim 1, wherein a root mean square surface roughness of the porous electrically conductive material proximate the first surface and the second surface of the substrate is less than about 300 nanometers.

7. The via of claim 1, wherein the porous electrically conductive material comprises copper, and
wherein the first porosity for a crack-free substrate is greater than or equal to about: 0.6263(d)-7.7368, where “d” is an average diameter of the through-hole greater than about 12 micrometers and less than about 100 micrometers.

8. The via of claim 1, wherein the porous electrically conductive material comprises silver, and
wherein the first porosity for a crack-free substrate is greater than or equal to about: 0.6(0.6263(d)-7.7368), where “d” is an average diameter of the through-hole greater than about 12 micrometers and less than about 100 micrometers.

9. A via comprising:
a substrate comprising a first surface and a second surface opposite to the first surface, the substrate comprising a through-hole extending from the first surface to the second surface;
a porous electrically conductive material extending completely through the through-hole; and
a cavity in the porous electrically conductive material in a central region of the through-hole.

10. The via of claim 9, wherein the porous electrically conductive material comprises a sintered electrically conductive paste comprising electrically conductive particles comprising a substantially uniform size.

11. The via of claim 9, wherein the substrate comprises a glass, a glass-ceramic, or a ceramic.

12. The via of claim 9, wherein the porous electrically conductive material comprises copper or silver.

13. The via of claim 9, wherein the cavity comprises a length greater than about one-fourth a distance between the first surface and the second surface of the substrate.

14. The via of claim 9, wherein a root mean square surface roughness of the porous electrically conductive material proximate the first surface and the second surface of the substrate is less than about 300 nanometers.

15. A method for fabricating a via, the method comprising:
forming a through-hole through a substrate from a first surface of the substrate to a second surface of the substrate opposite to the first surface;
filling the through-hole with a paste comprising an electrically conductive material;
sintering the paste to form a porous metallized through-hole comprising a first porosity; and
applying hot-isostatic pressure to the porous metallized through-hole to change the porosity of the porous metallized through-hole proximate the first surface and the second surface of the substrate to a second porosity less than the first porosity.

16. The method of claim 15, further comprising:
chemical-mechanical polishing the porous metallized through-hole to remove electrically conductive material on the first surface and the second surface of the substrate proximate the through-hole.

17. The method of claim 15, wherein applying hot-isostatic pressure to the porous metallized through-hole comprises applying hot-isostatic pressure to the porous metallized through-hole to form a cavity in the electrically conductive material in a central region of the through-hole.

18. The method of claim 15, wherein applying the hot-isostatic pressure comprises a temperature greater than or equal to about 300 degrees Celsius, a dwell time greater than or equal to about 30 minutes, and a pressure greater than or equal to about 4 megapascals.

19. The method of claim 15, wherein the substrate comprises a glass, a glass-ceramic, or a ceramic.

20. The method of claim 15, wherein forming the through-hole comprises forming a cylindrical through-hole, a tapered through-hole, or an hour-glass through-hole.
